(19) United States
(12) Patent Application Publication
(10) Pub. No.: US 2010/0230152 A1
(43) Pub. Date: Sep. 16, 2010

(54) METHOD OF SOLDERING ELECTRONIC COMPONENT, AND ELECTRONIC COMPONENT

(75) Inventor: Takahiro KITAGAWA, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/715,586

(22) Filed: Mar. 2, 2010

(30) Foreign Application Priority Data
Mar. 16, 2009 (JP) 2009-63352

(51) Int. Cl. H05K 1/16; B23K 31/02; B23K 1/20

(52) U.S. Cl. 174/260; 228/256

(57) ABSTRACT

A method of soldering an electronic component includes; providing solder onto a printed circuit board electrode of a printed circuit board; placing the electronic component over the printed circuit board, the electronic component having a component electrode to be mounted on the printed circuit board electrode with a component-supporting member that melts with heat interposed therebetween; and heating the solder and the component-supporting member. The electronic component is supported on one side thereof by the component-supporting member and on the opposite side thereof directly by the printed circuit board.

### CROSS-REFERENCE TO RELATED APPLICATION

This application is based upon and claims the benefit of priority of the prior Japanese Patent Application No. 2009-63352, filed on Mar. 16, 2009, the entire contents of which are incorporated herein by reference.

### FIELD

The embodiments discussed herein are related to methods of soldering electronic components and electronic components.

### BACKGROUND

Some methods of mounting electronic components on printed circuit boards with solder are proposed. For example, Japanese Patent Laid-Open Publication Nos. 8-293670 and 2000-68637 disclose techniques of suppressing the occurrence of residual voids in solder. In JP-A-8-293670, soldering is performed in a state where an electronic component is supported on opposite sides thereof by solder chips having a higher melting point and a larger thickness than solder foil provided over a printed circuit board. In JP-A-2000-68637, reflow heating is performed in a state where an electronic component is supported on opposite sides thereof by solder chips having different melting points and provided on solder paste applied over a printed circuit board. According to each of JP-A-8-293670 and JP-A-2000-68637, voids are let out of the solder, provided on an electrode of the printed circuit board, before the solder and the electronic component come into contact with each other, whereby occurrence of residual voids in the solder is suppressed.

In JP-A-8-293670, however, when the solder is heated, flux contained in the solder provided over the electrode of the printed circuit board may evaporate before the solder chips melt and the electronic component and the solder provided over the electrode of the printed circuit board come into contact with each other. If the flux evaporates, the wettability of the solder is reduced, resulting in the possibility of poor bonding.

In JP-A-2000-68637, since the solder chips supporting the respective sides of the electronic component have different melting points, the electronic component is temporarily tilted during reflow heating. Because of the difference in melting point between the solder chips, there is always a time lag from when one of the two solder chips melts until when the other solder chip melts. During the time lag, the flux may evaporate. This may reduce solder wettability and consequently cause poor bonding.

### SUMMARY

According to an embodiment, a method of soldering an electronic component includes; providing solder onto a printed circuit board electrode of a printed circuit board; placing the electronic component over the printed circuit board, the electronic component having a component electrode to be mounted on the printed circuit board electrode with a component-supporting member that melts with heat interposed therebetween; and heating the solder and the component-supporting member. The electronic component is supported on one side thereof by the component-supporting member and on the opposite side thereof directly by the printed circuit board.

It is to be understood that both the foregoing general description and the following detailed description are exemplary, and do not restrict the invention as claimed.

### BRIEF DESCRIPTION OF DRAWINGS

The above and other features and advantages of the present invention will become apparent from the following description of the embodiments in conjunction with the accompanying drawings, wherein:

FIGS. 1A to 1C illustrate a method of soldering an electronic component;

FIGS. 2A to 2C illustrate the method of soldering an electronic component;

FIGS. 3A to 3C illustrate the method of soldering an electronic component;

FIGS. 4A to 4C illustrate a method of soldering an electronic component according to a comparative example;

FIGS. 5A and 5B illustrate a method of manufacturing an electronic component according to a variation;

FIGS. 6A to 6C illustrate the method of manufacturing an electronic component according to the variation;

FIGS. 7A to 7C illustrate the method of manufacturing an electronic component according to the variation;

FIG. 8 illustrates conditions of an experiment;

FIGS. 9A and 9B are X-ray photographs of electronic component units;

FIGS. 10A and 10B are X-ray photographs of electronic component units;

FIGS. 11A and 11B are X-ray photographs of electronic component units; and

FIG. 12 illustrates a printed circuit board according to another variation.

### DESCRIPTION OF EMBODIMENTS

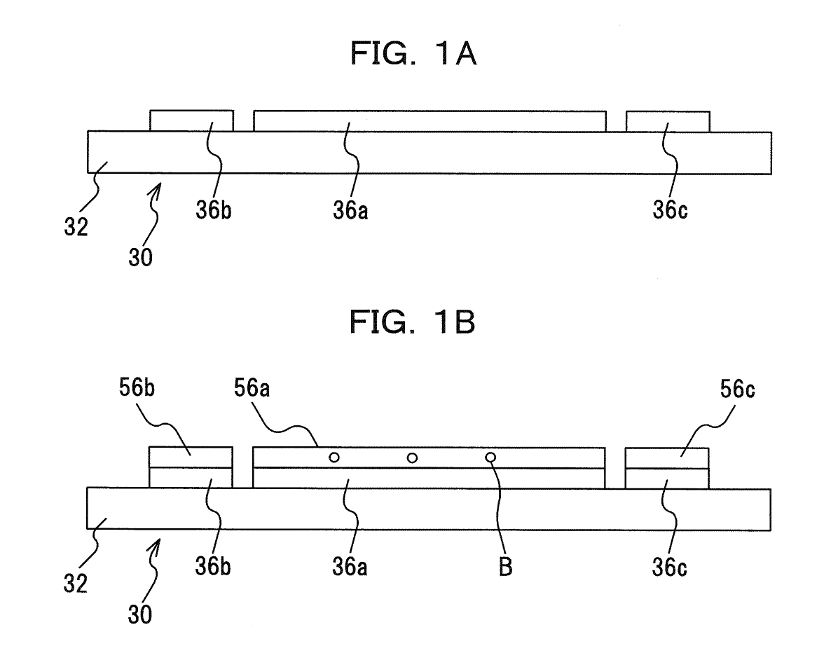

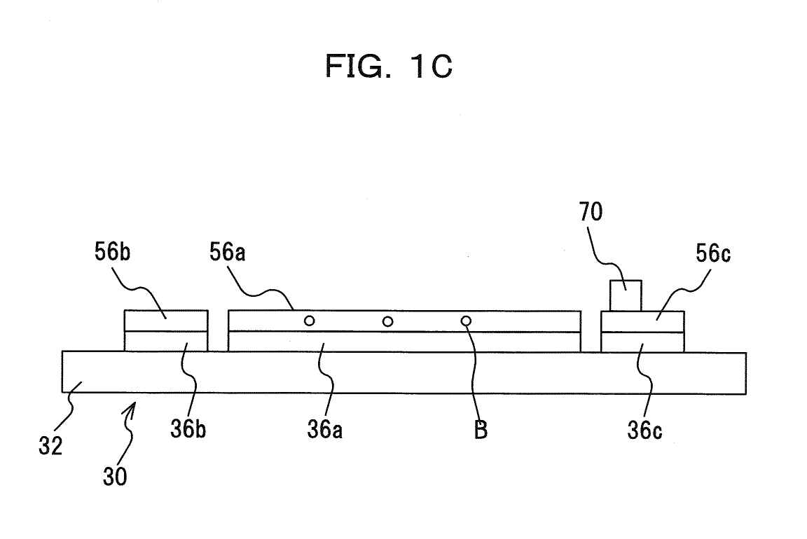

FIGS. 1A to 3C illustrate a method of soldering an electronic component. Referring to FIG. 1A, an electronic component unit includes a printed circuit board 30 and an electronic component 10. The electronic component 10 will be described separately below. The printed circuit board 30 includes a base 32 and electrodes 36a to 36c provided on the top surface of the base 32. The base 32 is a hard printed wiring board having a specific pattern printed thereon. The electrodes 36a to 36c are electrically connected to the pattern on the base 32. The electrode 36a is positioned in the center portion of the base 32. The electrodes 36b and 36c are each positioned near an edge of the base 32 with respect to the center thereof. The electrode 36a has a larger surface area than each of the electrodes 36b and 36c.

A process of providing a first solder will now be described. Referring to FIG. 1B, solders 56a to 56c are applied over the top surfaces of the electrodes 36a to 36c. The solders 56a to 56c are in a paste form, for example. The solder 56a contains a plurality of voids B. The solders 56a to 56c may be applied by screen printing, nozzle ejection, or the like. The solders 56a to 56c are each a mixture of solder powder and flux. The flux is composed of an activator, a thickener, a thixotropic agent, a solvent, and so forth. The solders 56a to 56c are lead-free.

A process of providing a second solder will now be described. Referring to FIG. 1C, a solder chip 70 is placed on the solder 56c. The solder chip 70 has a higher melting point and a larger height than the solders 56a to 56c. The solder chip 70 may alternatively be placed on the solder 56a, as long as the solder chip 70 is placed near an edge of the base 32 with respect to the center thereof. The solder chip 70 may not necessarily contain flux.

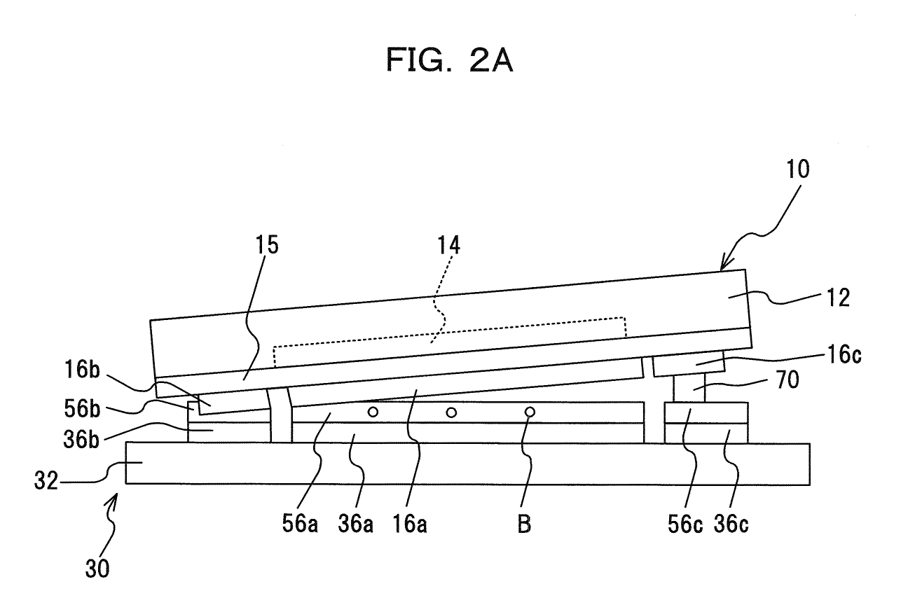

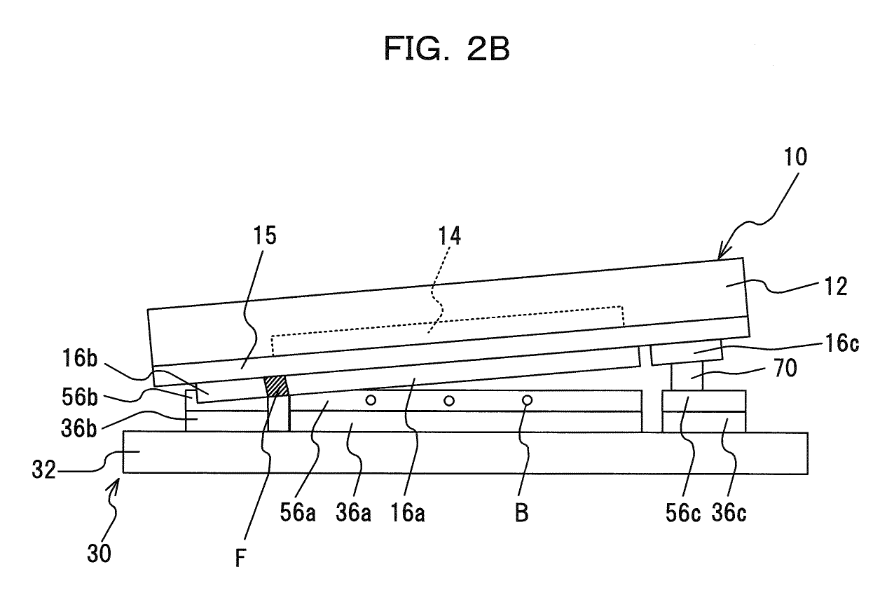

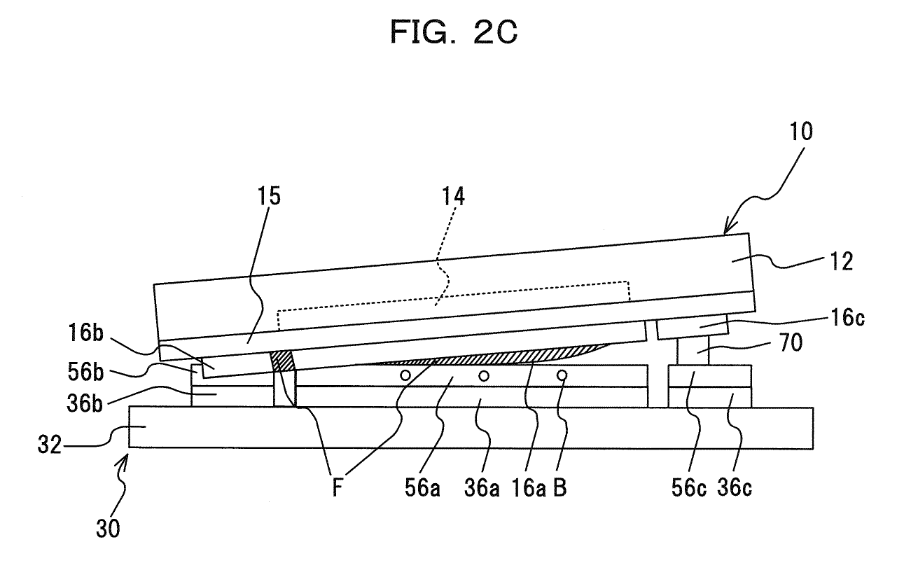

A process of placing the electronic component 10 over the printed circuit board 30 will now be described. The electronic component 10 is first placed over the printed circuit board 30 as illustrated in FIG. 2A. The electronic component 10 includes a resin body 12, a semiconductor chip 14, a substrate 15, and electrodes 16a to 16c. A set of the resin body 12, the semiconductor chip 14, and the substrate 15 may be regarded as a component body of the invention. The electronic component 10 has a substantially rectangular shape. The semiconductor chip 14 is mounted on the top surface of the substrate 15. The resin body 12 seals the semiconductor chip 14. The electrodes 16a to 16c are provided on the bottom surface of the substrate 15. The electrodes 16a to 16c are electrically connected to a wiring pattern provided on the substrate 15. The electrode 16a is positioned in the center portion of the substrate 15. The electrodes 16b and 16c are each positioned near an edge of the substrate 15 with respect to the center thereof. The electrode 16a has a larger surface area than each of the electrodes 16b and 16c.

The electronic component 10 is placed over the printed circuit board 30 so that the electrode 16c is positioned on the solder chip 70. The electrode 16b is positioned on the solder 56b. With the solder chip 70, the electronic component 10 is tilted with respect to the printed circuit board 30. The electronic component 10 may be tilted with respect to the printed circuit board 30 by positioning the solder chip 70 near an edge of the printed circuit board 30 with respect to the center thereof and near an edge of the electronic component 10 with respect to the center thereof. The solder chip 70 may be regarded as a component-supporting member of the invention, which supports one side of the electronic component 10. The solder chip 70 melts with heat. The side of the electronic component 10 opposite the side supported by the solder chip 70 is supported by the printed circuit board 30.

In this state, the electrode 16b slightly sinks into the solder 56b which is in a paste form, and a part of the electrode 16a is in contact with the solder 56a before heating is performed.

A process of heating the solders 56a to 56c and the solder chip 70 will now be described. With the electronic component 10 being tilted with respect to the printed circuit board 30, the set of the electronic component 10 and the printed circuit board 30 is conveyed into a reflow oven and is heated therein. Thus, the solders 56a to 56c and the solder chip 70 are heated.

When heating is started in the reflow oven, the solders 56a to 56c start to melt before the solder chip 70 starts to melt. This is because the melting points of the solders 56a to 56c are lower than the melting point of the solder chip 70. When the solders 56a and 56b start to melt, referring to FIG. 2B, some flux F contained in the solders 56a and 56b adheres to the electrodes 16a and 16b.

When the heating is continued, referring to FIG. 2C, the flux F spreads over the surface of the electrode 16a. The spreading of the flux F over the surface of the electrode 16a improves the wettability of the solder 56a.

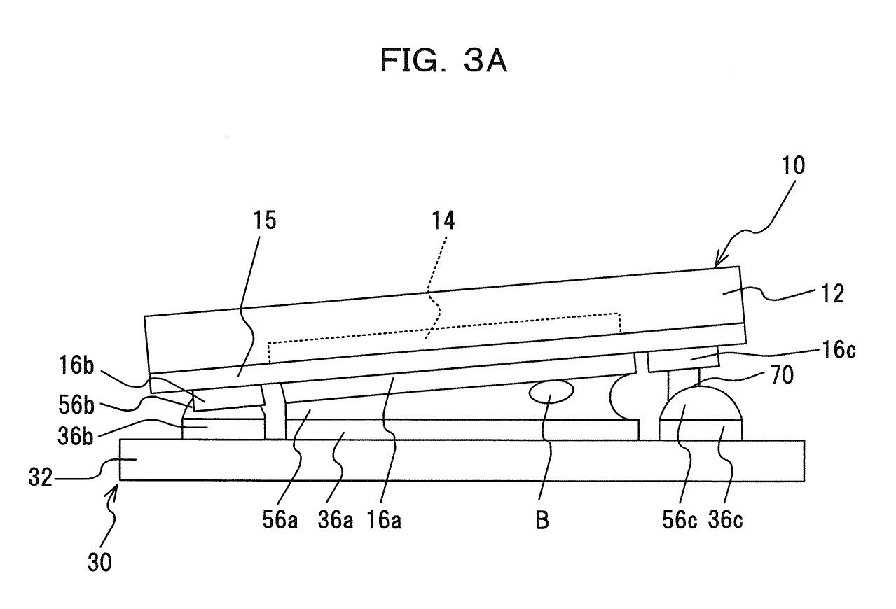

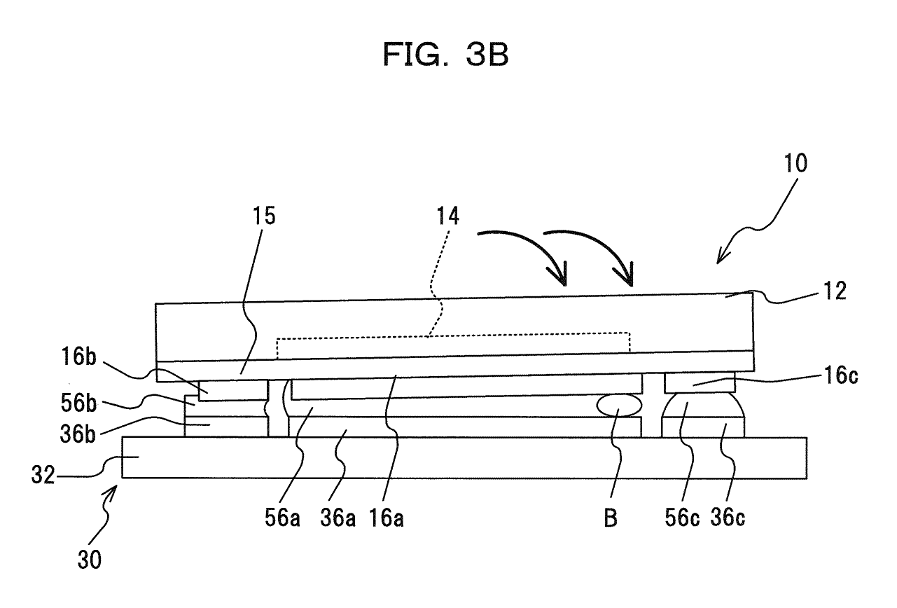

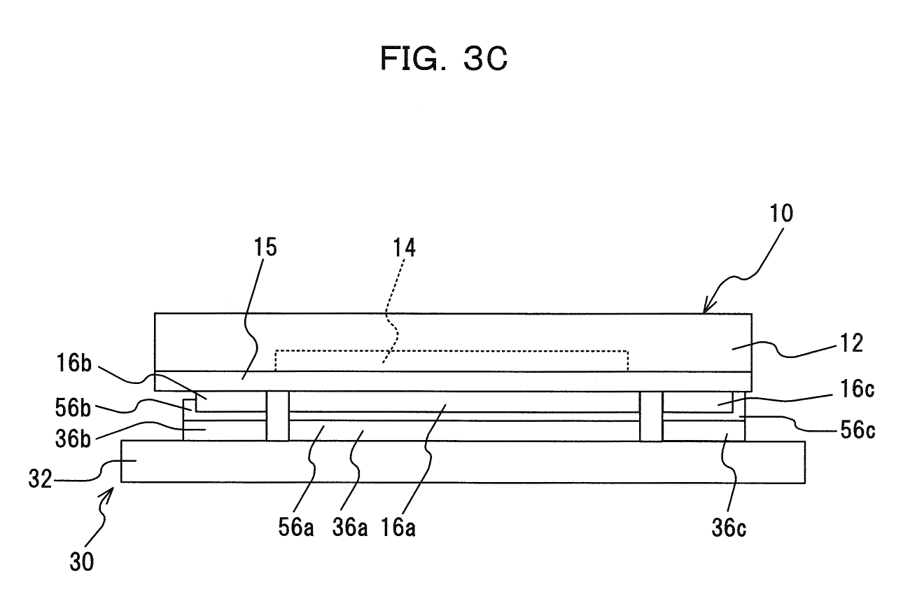

When the heating is further continued, referring to FIG. 3A, the solder 56a in the melted state adheres to the entire surface of the electrode 16a due to the surface tension thereof. In this process, the plurality of voids B are combined together in the solder 56a, producing a large void B. The large void B moves upward along the surface of the electrode 16a under its own buoyancy, thereby slowly moving toward an edge of the electrode 16a.

When the heating is further continued, most of the solder chip 70 melts and is fused with the solder 56c. Thus, referring to FIG. 3C, the electrode 16a is brought closer to the electrode 36a under the weight of the electronic component 10. The void B in the solder 56a is slowly squeezed between the electrode 16a and the electrode 36a, thereby being pushed out of the solder 56a. Meanwhile, the electronic component 10 becomes substantially parallel to the printed circuit board 30 under its own weight and due to the surface tension of the solders 56a to 56c. When the set of the electronic component 10 and the printed circuit board 30 in such a state is conveyed out of the reflow oven, the solders 56a to 56c are hardened, whereby mounting of the electronic component 10 onto the printed circuit board 30 is completed. Thus, an electronic component unit is manufactured.

In the above soldering method, since part of the electrode 16a is in contact with the solder 56a before heating is performed, the flux F starts to spread from the contact part before evaporating completely. In other words, the viscosity of the flux F decreases with increasing temperature, and the flux F spreads along the electronic component 10, improving the wettability of the solder 56a. This suppresses the occurrence of residual voids in the solder 56a, realizing good soldering.

The electrode 36c facing the solder chip 70 has an area corresponding to the total mass of the solder 56c and the solder chip 70. Therefore, the solder 56c and the solder chip 70, when melted with heat, are prevented from flowing off the electrode 36c.

Another case will now be described in which the electronic component 10 is placed over the printed circuit board 30 with a tilt with respect thereto but with the solder 56a and the electrode 16a not being in contact with each other. When the solder 56a is heated in such a state, the solder 56a melts and is liquefied, thereby having an increased surface area. With the increase in the surface area of the solder 56a, part of the liquefied solder 56a nearest to the electrode 16a comes into contact with part of the electrode 16a. This causes the flux F in the solder 56a to spread over the surface of the electrode 16a. Thus, even if the electronic component 10 is placed over the printed circuit board 30 with the solder 56a and the electrode 16a not being in contact with each other, the wettability of the solder 56a is improved. Moreover, when the solders 56b and 56c melt with heat, the electrode 16b further sinks into the solder 56b and the solder chip 70 sinks into the solder 56c under the weight of the electronic component 10. Thus, even if the electrode 16a and the solder 56a are not in contact with each other before heating is started, part of the electrode 16a and part of the solder 56a may come into contact with each other in a short time after heating is started.

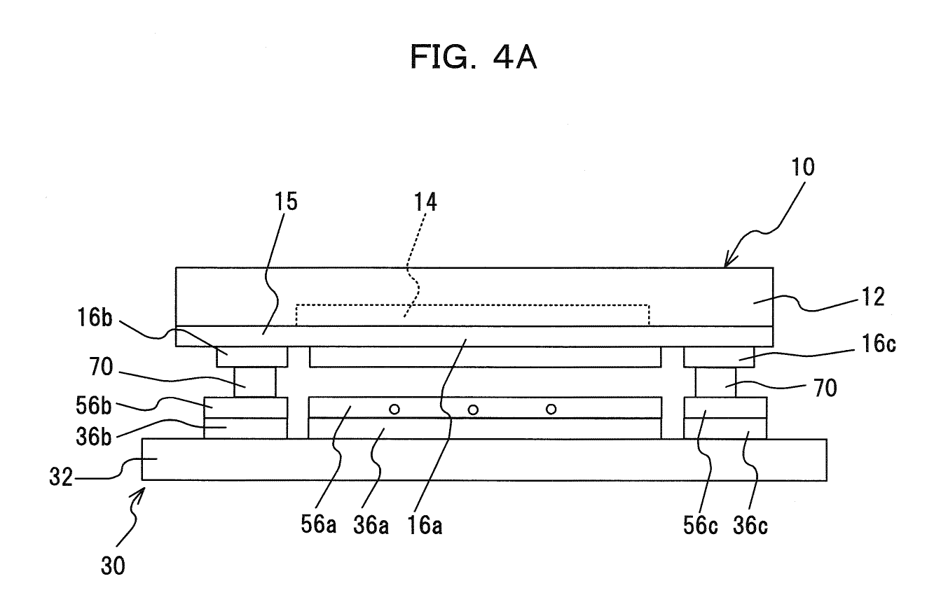

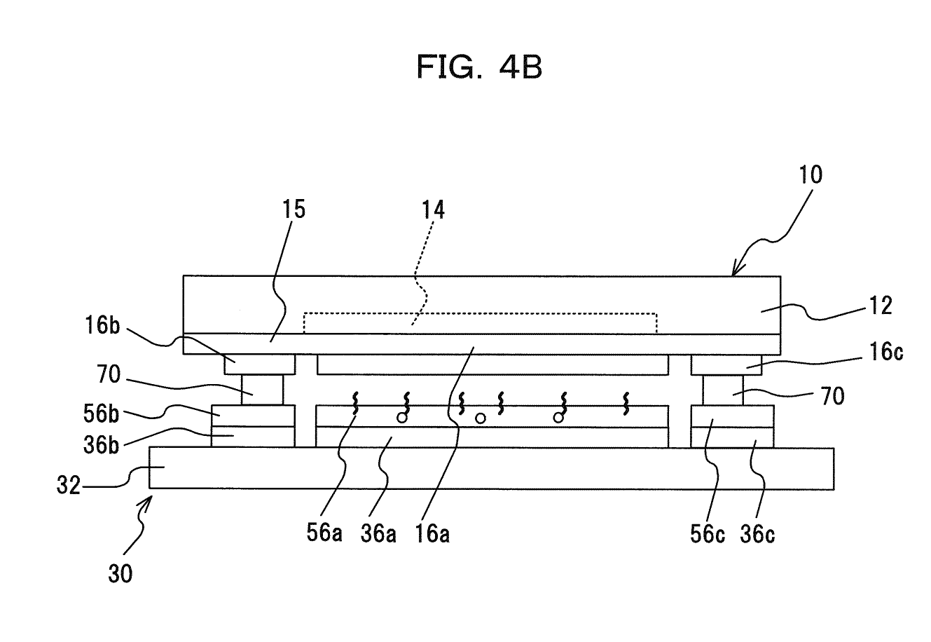

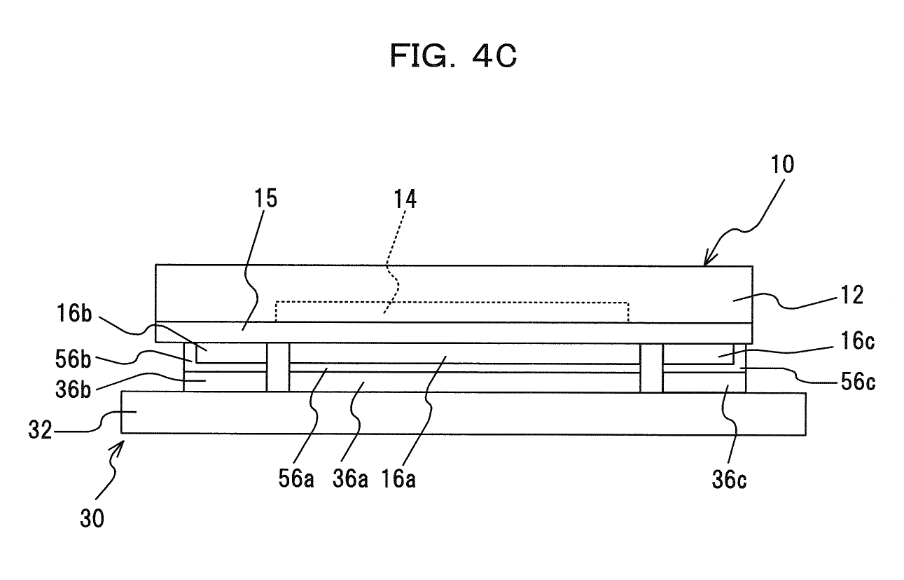

A comparative method of soldering an electronic component will now be described. Referring to FIG. 4A, the solder chip 70 is placed on each of the solders 56b and 56c, whereby the electronic component 10 is placed parallel to the printed circuit board 30. In this state, the solder 56a and the electrode 16a are not in contact with each other. The set of the electronic component 10 and the printed circuit board 30 in this state is heated in a reflow oven. When heating is started, the flux F in the solder 56a starts to evaporate. The evaporation lasts until the solder 56a comes into contact with the electrode 16a.

When heating is further continued, referring to FIG. 4C, the two solder chips 70 melt, whereby the solder 56a comes into contact with the electrode 16a. When the set of the electronic component 10 and the printed circuit board 30 in this state is conveyed out of the reflow oven, the solders 56a to 56c are hardened. Thus, mounting of the electronic component 10 onto the printed circuit board 30 is completed.

In the comparative method, the flux F in the solder 56a evaporates during the period from when the solder 56a starts to be heated until when the solder 56a and the electrode 16a come into contact with each other with the melting of the two solder chips 70. Therefore, in the comparative method, the wettability of the solder 56a is reduced, and the bonding strength provided by the solder 56a may be reduced.

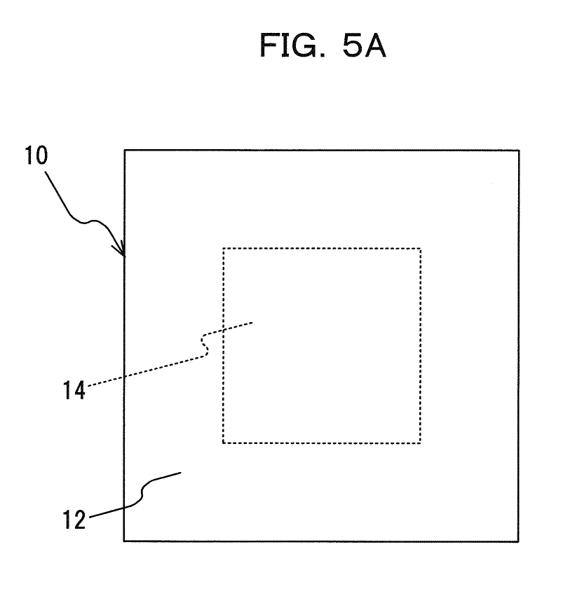

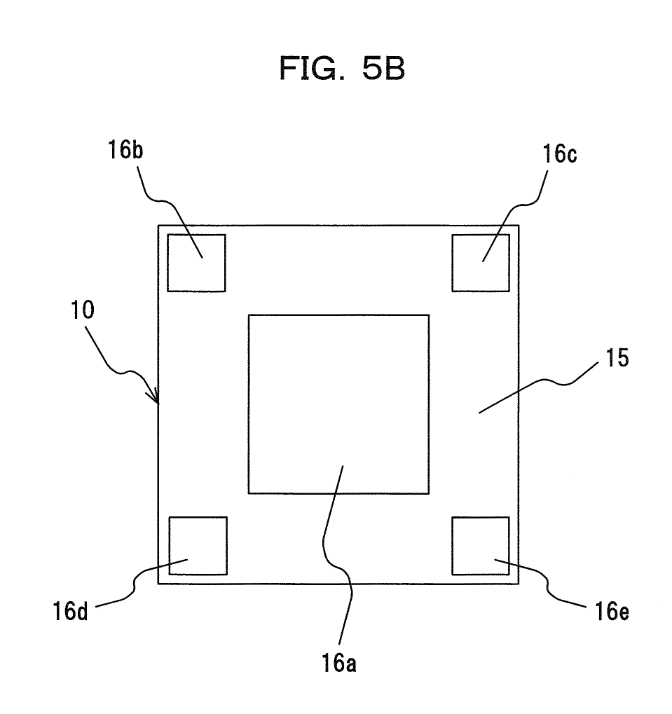

Variations of the electronic component will now be described. FIGS. 5A to 7C illustrate a method of manufacturing an electronic component according to a variation. FIG. 5A is a top view of an electronic component 10. FIG. 5B is a bottom view of the electronic component 10. The electronic component 10 has on the bottom surface thereof electrodes 16a to 16e. The electrodes 16b to 16e are positioned at the corners of the substrate 15, respectively. The electronic component 10 illustrated in FIGS. 5A and 5B is the same as the electronic component 10 illustrated in FIG. 2A and others. The electrodes 16b to 16e have substantially the same size. A case where solder chips 70 are provided on the electrodes 16c and 16e of the electronic component 10 configured as above will now be described.

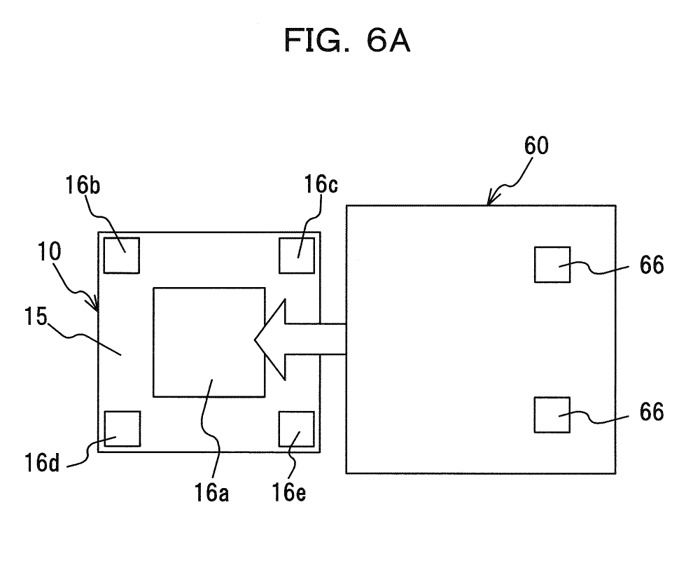

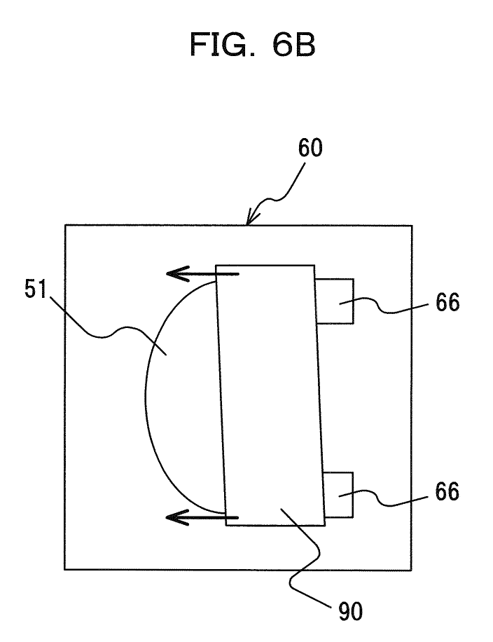

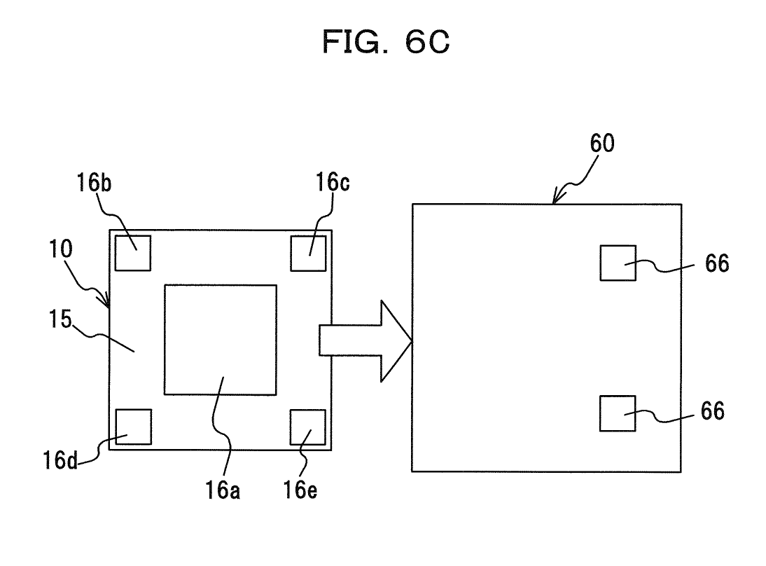

Referring to FIG. 6A, a mask 60 is placed on the bottom surface of the electronic component 10. The mask 60 has holes 66 therein at positions corresponding to the electrodes 16c and 16e. Referring to FIG. 6B, solder 51 in a paste form is applied with a squeegee 90 onto the mask 60 placed over the bottom surface of the electronic component 10. Referring to FIG. 6C, when the mask 60 is removed from the bottom surface of the electronic component 10, only the electrodes 16c and 16e have layers of the solder 51 thereon.

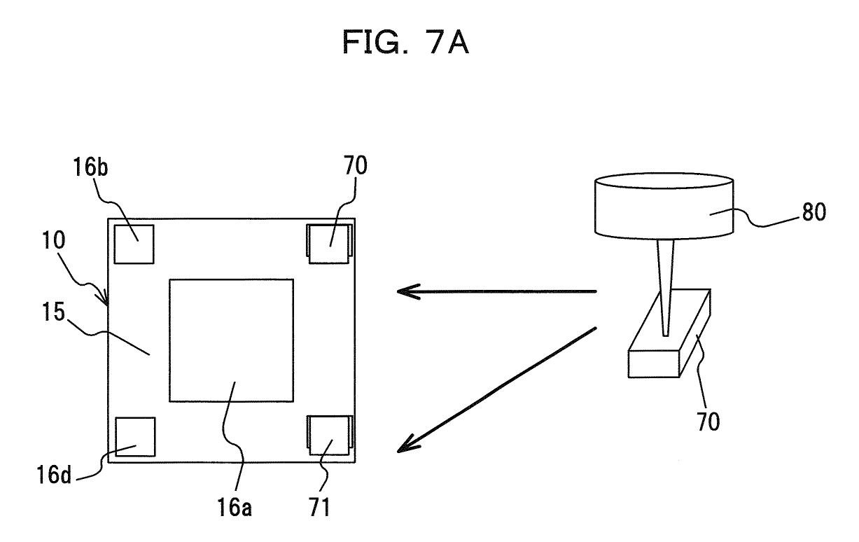

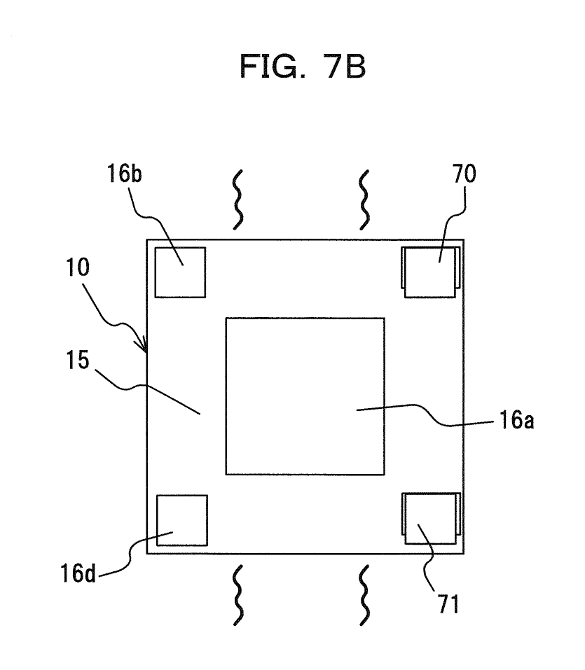

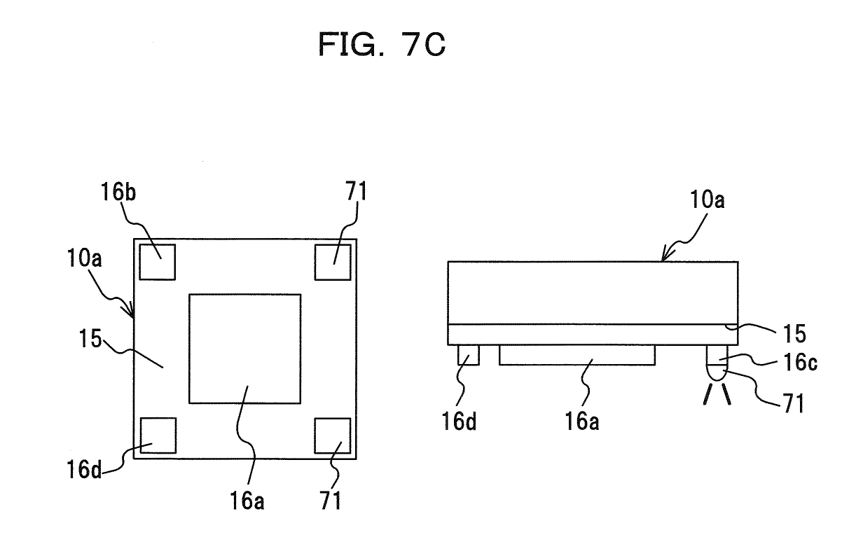

Referring to FIG. 7A, the solder chips 70 are mounted onto the respective electrodes 16c and 16e with a mounter 80. Referring to FIG. 7B, the electronic component 10 is conveyed into a reflow oven, whereby the solder chips 70 are melted. When the solder chips 70 melt, the solder chips 70 are fused with the respective layers of the solder 51. Then, the electronic component 10 is conveyed out of the reflow oven. Referring to FIG. 7C, the fused bodies of the solder chips 70 and the layers of the solder 51 are hardened, whereby projecting solders 71 are formed on the respective electrodes 16c and 16e. Thus, an electronic component 10a having the projecting solders 71 is obtained.

When the electronic component 10a having the projecting solders 71 is placed on a flat surface with the electrodes 16a to 16e face down, the electronic component 10a is tilted with respect to the flat surface. The electronic component 10a having such a configuration may be placed over the printed circuit board 30 with a tilt with respect thereto. In this case, there is no need to provide solder chips on the printed circuit board 30. The electronic component 10a having the projecting solders 71 is placed over the printed circuit board 30, and the set of the electronic component 10a and the printed circuit board 30 is conveyed into a reflow oven and is heated. Thus, an electronic component unit is manufactured.

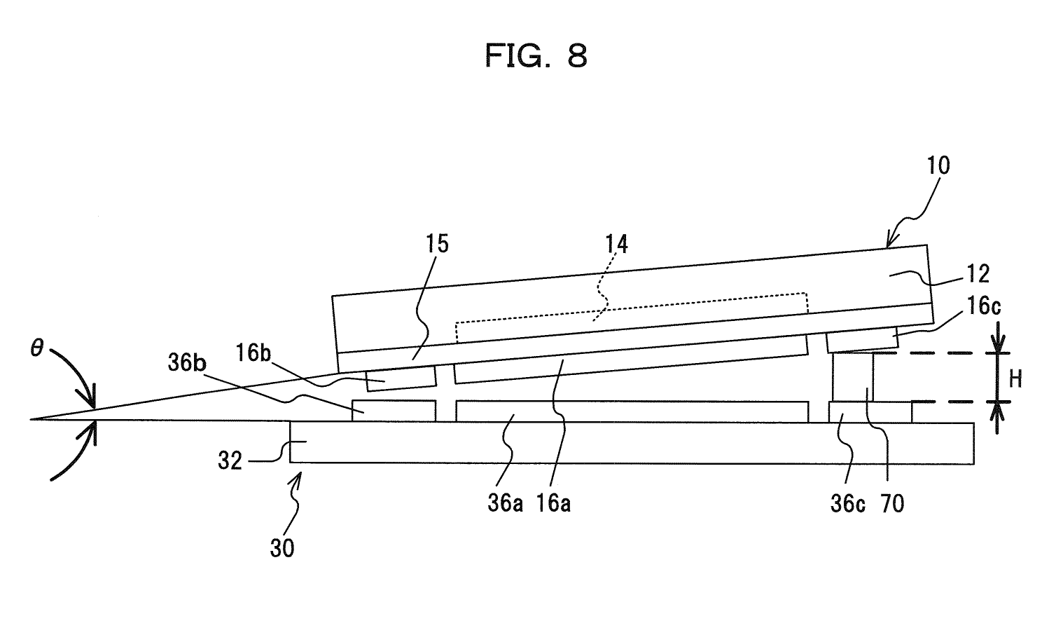

The occurrence of residual voids will now be described. To examine the occurrence of residual voids, the present inventor conducted an experiment. FIG. 8 illustrates conditions of the experiment. The experiment was conducted with an electronic component 10 having a short-side dimension of 9 mm and a long-side dimension of 9.5 mm, and solder chips 70 having different heights H of 0.3 mm, 0.5 mm, and 0.8 mm. The angle θ formed between the substrate 15 and the surfaces of the electrodes 36a to 36c was 1.91 degrees for the height H of 0.3 mm, 3.18 degrees for the height H of 0.5 mm, and 5.10 degrees for the height H of 0.8 mm.

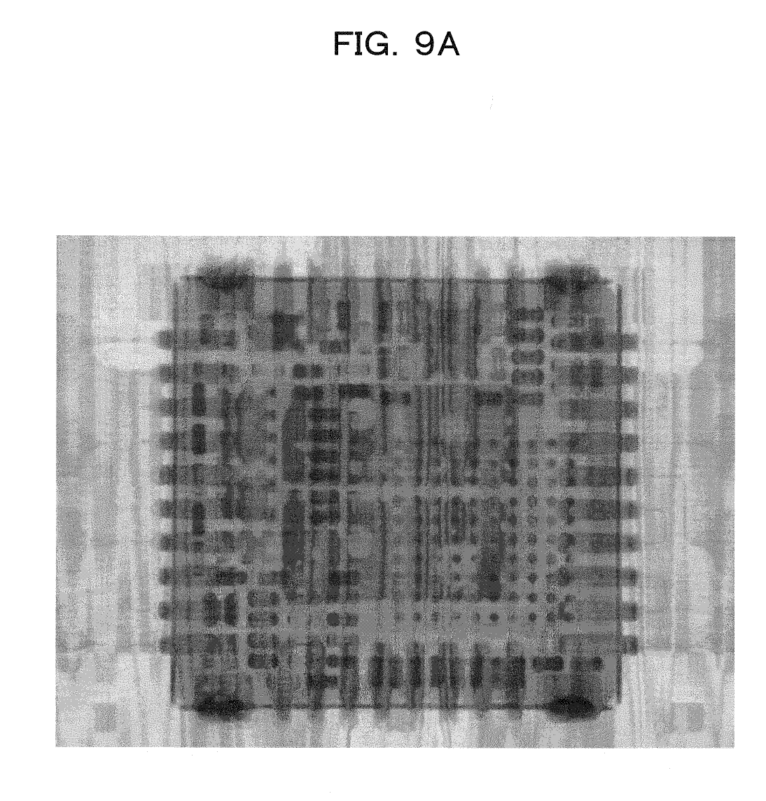

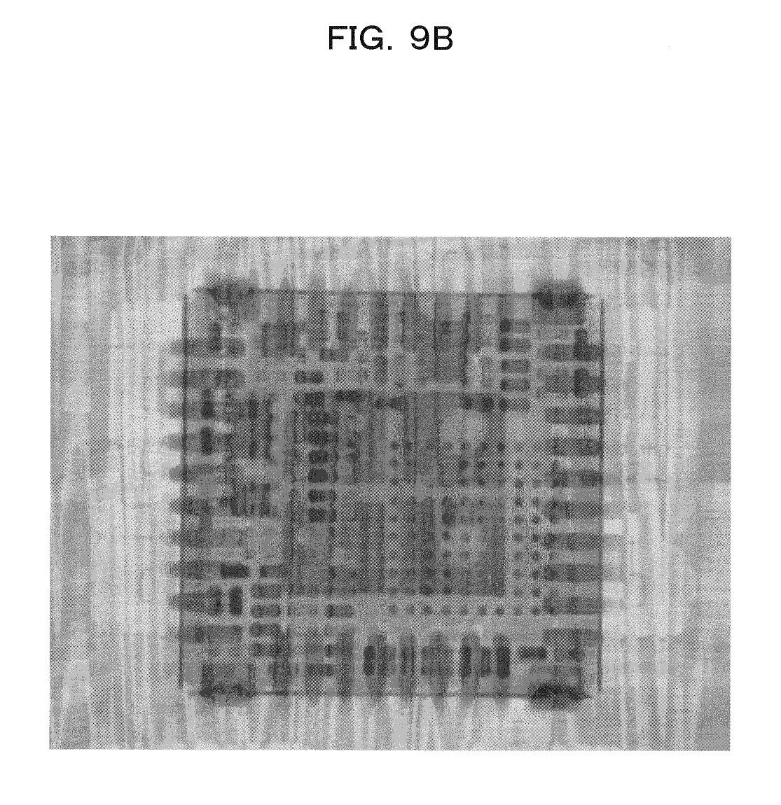

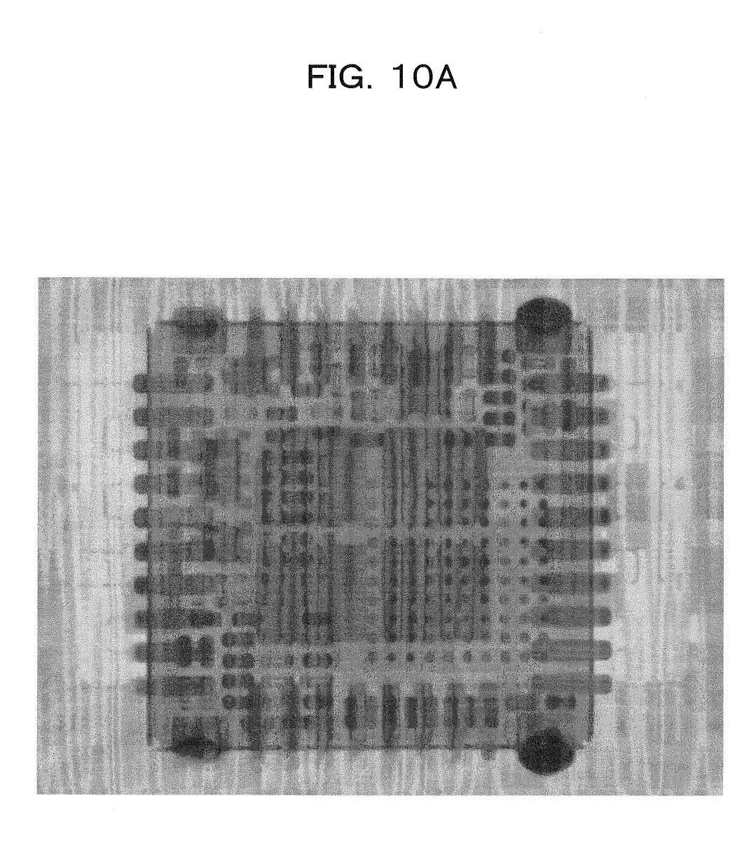

FIGS. 9A to 11B are X-ray photographs of different electronic component units. FIG. 9A illustrates an X-ray photograph of an electronic component unit without solder chips 70, that is, where the electronic component 10 was mounted on the printed circuit board 30 only with solder in a paste form, applied over the electrode 36a and others, interposed therebetween. Referring to FIG. 9A, a plurality of large voids B remains in the central region.

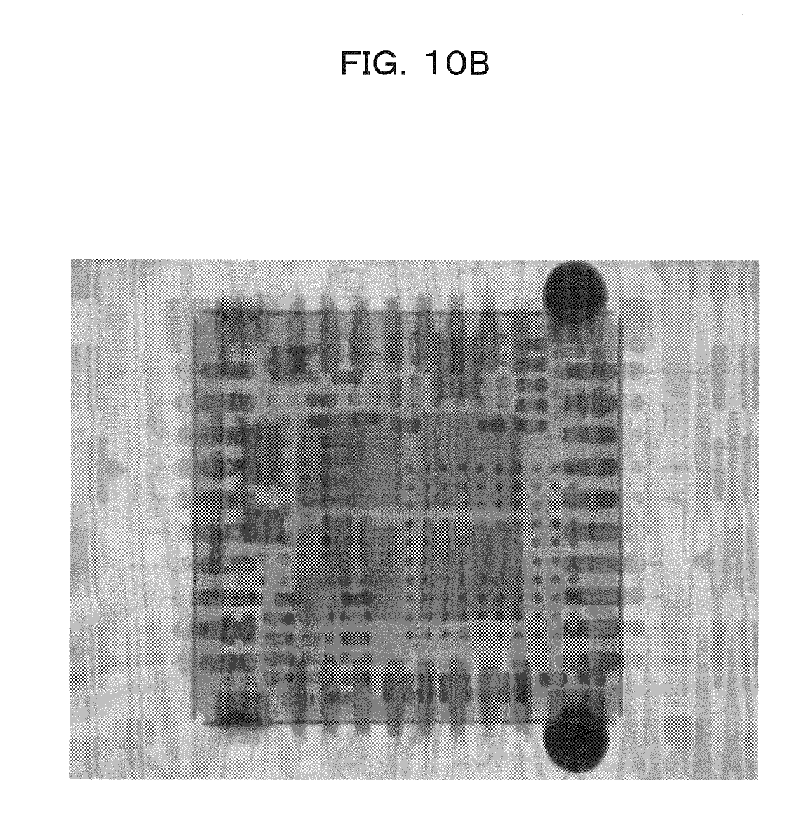

FIG. 9B is an X-ray photograph of an electronic component unit in which the electronic component 10 was mounted on the printed circuit board 30 with solder chips 70 having the height H of 0.3 mm interposed therebetween. As may be seen from FIG. 9B, a plurality of large voids B still remains in the central region. FIGS. 9B to 10B each illustrate a case where a solder chip 70 was placed at each of two, i.e., upper right and lower right, of the four corners of the electronic component 10.

FIG. 10A is an X-ray photograph of an electronic component unit in which the electronic component 10 was mounted on the printed circuit board 30 with solder chips 70 having the height H of 0.5 mm interposed therebetween. Compared with the case where no solder chips 70 were provided and the case where the solder chips 70 having the height H of 0.3 mm were provided, it is apparent that the amount of residual voids B is markedly reduced.

FIG. 10B is an X-ray photograph of an electronic component unit in which the electronic component 10 was mounted on the printed circuit board 30 with solder chips 70 having the height H of 0.8 mm interposed therebetween. As may be seen from FIG. 10B, the amount of residual voids B is further reduced.

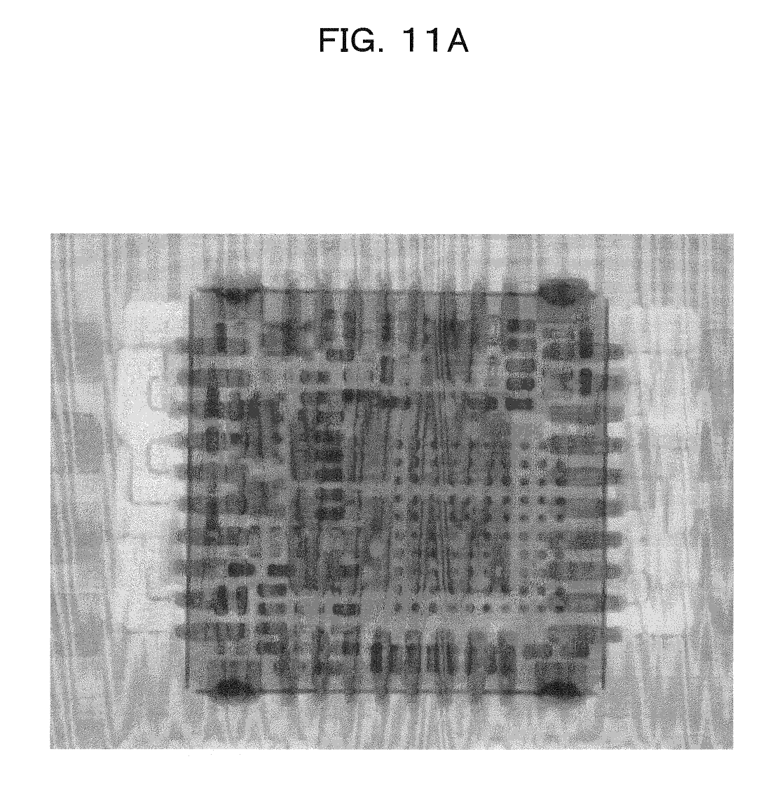

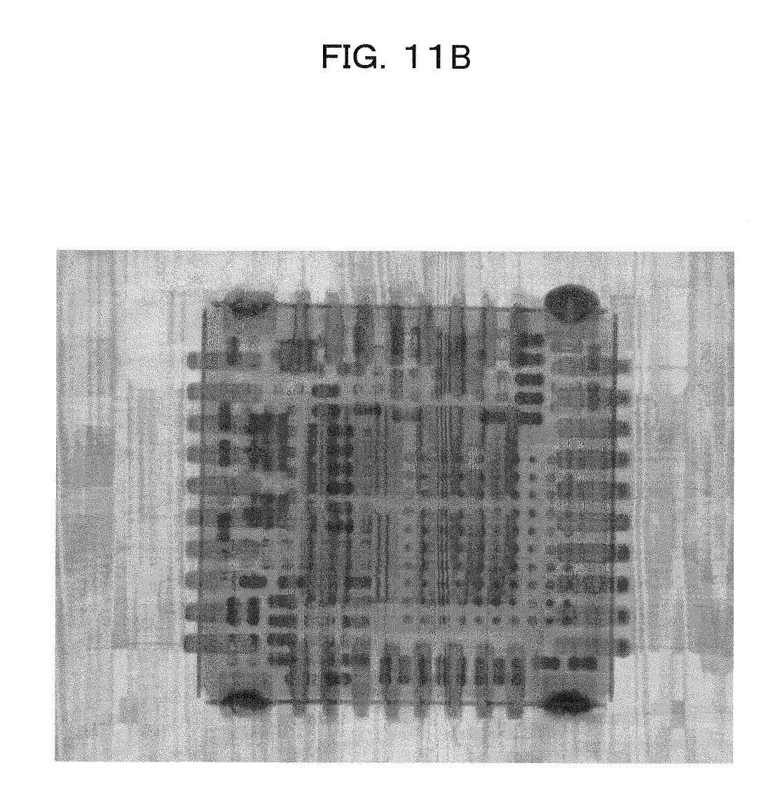

FIGS. 11A and 11B are each an X-ray photograph of an electronic component unit in which a solder chip 70 was placed at only one, i.e., upper right, of the four corners of the electronic component 10. FIG. 11A illustrates a case where the electronic component 10 was mounted on the printed circuit board 30 with a solder chip 70 having the height H of 0.3 mm interposed therebetween. Many voids B may be seen. FIG. 11B illustrates a case where the electronic component 10 was mounted on the printed circuit board 30 with a solder chip 70 having the height H of 0.5 mm interposed therebetween. Although a few voids B remain in FIG. 11B, the amount of residual voids B in FIG. 11B is markedly reduced, compared with the case illustrated in FIG. 11A.

As described above, even with a single solder chip 70, the amount of residual voids was effectively reduced. The results of the experiment also illustrate that the amount of residual voids was effectively reduced when the angle θ was about 3 degrees or larger. In addition, in the cases where two solder chips 70 were provided, the electronic component 10 was supported more stably than in the cases where only a single solder chip 70 was provided.

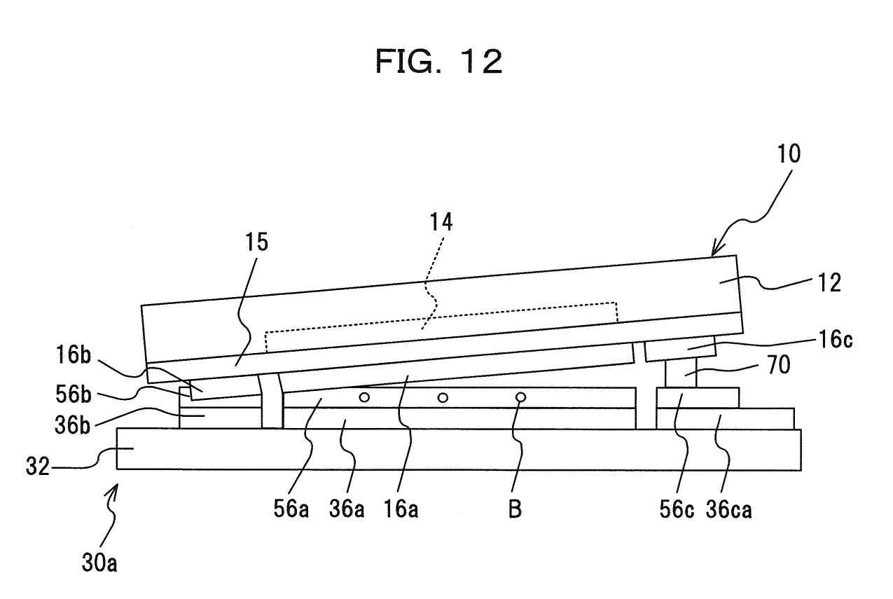

A printed circuit board according to another variation will now be described. FIG. 12 illustrates a printed circuit board 30a according to another variation. Referring to FIG. 12, an electrode 36ca facing a solder chip 70 extends outward beyond an edge of an electronic component 10. The reason for this is as follows. Depending on the size and other factors of the solder chip 70, the electronic component 10 may be mounted at a high position. If the electrode 36ca facing the solder chip 70 is made to extend outward beyond the edge of the electronic component 10 to be mounted thereon, the solder chip 70 in a melted state is able to flow outside of the electronic component 10. Thus, the position at which the electronic component 10 is to be mounted is reduced if not prevented from becoming high.

While a preferred embodiment of the present invention has been described, the present invention is not limited to a specific embodiment, and various changes and modifications may be made thereto within the scope of the present invention defined by the appended claims.

While the above embodiment concerns a case where the solder chip has a higher melting point than the solder, the solder chip and the solder may have the same melting point. This is because it takes a certain period of time for the flux contained in the solder provided under the solder chip to be liquefied and fused with the solder chip.

While the above embodiment concerns an electronic component in which a semiconductor chip is sealed by a resin body, the present invention is not limited thereto. For example, an electronic component in which a semiconductor chip is encapsulated by a metal lid, instead of being sealed by a resin body, is also acceptable.

While the above embodiment employs solder chips, an electronic component may alternatively be supported at one side thereof by any other member that melts with heat.

Examples of embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made therein without departing from the spirit and scope of the present invention as set forth in the claims.

1. A method of soldering an electronic component, the method comprising:
providing solder onto a printed circuit board electrode of a printed circuit board,
placing the electronic component over the printed circuit board, the electronic component having a component electrode to be mounted on the printed circuit board electrode with a component-supporting member interposed therebetween that melts with heat, the electronic component supported on one side thereof by the component-supporting member and on the opposite side thereof directly by the printed circuit board; and
heating the solder and the component-supporting member.

2. The method of soldering an electronic component according to claim 1, wherein the solder and a part of the component electrode are in contact with each other before the heating is performed, and the electronic component is tilted with respect to the printed circuit board with the component-supporting member interposed therebetween.

3. The method of soldering an electronic component according to claim 1, wherein the component-supporting member has a larger height than the solder.

4. The method of soldering an electronic component according to claim 1, wherein the component-supporting member has a higher melting point than the solder.

5. The method of soldering an electronic component according to claim 1, wherein at least one of the solder and the component-supporting member is composed of lead-free solder.

6. The method of soldering an electronic component according to claim 1, wherein the component-supporting member is provided on the printed circuit board electrode.

7. The method of soldering an electronic component according to claim 1, wherein the component-supporting member is provided on the component electrode.

8. The method of soldering an electronic component according to claim 1, wherein the printed circuit board electrode facing the component-supporting member extends outward beyond an edge of the electronic component.

9. The method of soldering an electronic component according to claim 1, wherein the printed circuit board electrode facing the component-supporting member has an area corresponding to a total mass of the solder and the component-supporting member.

10. An electronic component to be mounted on a printed circuit board, the electronic component comprising:
a component body;
a component electrode provided on the component body; and
a component-supporting member that melts with heat, that is provided on the component electrode, and that supports one side of the electronic component on the printed circuit board.
